(19) United States
(12) Patent Application Publication
(10) Pub. No.: US 2011/0074050 A1
(43) Pub. Date: Mar. 31, 2011

(54) FILM FOR SEMICONDUCTOR DEVICE

(76) Inventors: Yasuhiro Amano, Osaka (JP); Yuuichirou Shishido, Osaka (JP); Kouichi Inoue, Osaka (JP)

(21) Appl. No.: 12/890,909

(22) Filed: Sep. 27, 2010

(30) Foreign Application Priority Data
Sep. 28, 2009 (JP) 2009-223095

(51) Int. Cl. B32B 33/00; H01L 29/00

(52) U.S. Cl. 257/798; 428/40.1; 257/E29.001

(57) ABSTRACT

The present invention provides a film for a semiconductor device, which is capable of preventing interface delamination between each of the films, a film lifting phenomenon, and transfer of the adhesive film onto the cover film even during transportation or after long-term storage in a low temperature condition. The film for a semiconductor device of the present invention is a film in which an adhesive film and a cover film are sequentially laminated on a dicing film, in which a peel force F₁ between the adhesive film and the cover film in a T type peeling test is within a range of 0.025 to 0.075 N/100 mm, a peel force F₂ between the adhesive film and the dicing film is within a range of 0.08 to 10 N/100 mm, and F₁ and F₂ satisfy a relationship of F₁<F₂.

### BACKGROUND OF THE INVENTION

1. Field of the Invention

The present invention relates to a film for a semiconductor device that is used in dicing of a workpiece when an adhesive for fixing a chip-shaped workpiece such as a semiconductor chip and an electrode member together is provided on a workpiece such as a semiconductor wafer before dicing. Further, the present invention relates to a semiconductor device that is manufactured using the film for a semiconductor device.

2. Description of the Related Art

A semiconductor wafer having a circuit pattern has its thickness adjusted by backside polishing as necessary, and then diced into semiconductor chips (a dicing step). Next, the semiconductor chips are fixed to an adherend such as a lead frame using an adhesive (a die attaching step), and then transferred to a bonding step. In the die attaching step, an adhesive is applied onto the lead frame or the semiconductor chips. However, with this method, it is difficult to make a uniform adhesive layer, and a special apparatus and a long time are required for the application of the adhesive. Accordingly, a dicing die bond film has been proposed in which an adhesive layer for fixing a chip that is necessary in the mounting step is provided while maintaining the adhesion of the semiconductor wafer in the dicing step (for example, refer to Japanese Patent Application Laid-Open No. 60-57642).

The dicing die bond film described in the above-described publication is formed by sequentially laminating a pressure-sensitive adhesive layer and an adhesive layer on a base material, with the adhesive layer in a peelable state. That is, a semiconductor wafer is diced while being held by the adhesive layer, the semiconductor chips are peeled together with the adhesive layer by stretching the base material, the chips are individually collected and fixed to an adherend such as a lead frame with the adhesive layer interposed.

The dicing die bond film of this type may cure when it is placed in a high temperature and high humidity environment or when it is stored for a long time under a load. As a result, a decrease in the fluidity of the adhesive layer, a decrease in the holding strength to the semiconductor wafer, and a decrease in the peeling property after dicing are brought about. Accordingly, a dicing die bond film is often transported while being stored in a frozen condition of −30 to −10° C. or a refrigerated condition of −5 to 10° C., which enables long-term maintenance of the film characteristics.

However, a conventional dicing die bond film is produced by producing a dicing film and a die bond film separately and then pasting both films with each other due to manufacturing restrictions. Accordingly, the conventional dicing die bond film is produced while applying a tensile force to each film during conveyance by a roll from the viewpoint of preventing sagging, displacement of winding, positional shift, voids (air bubbles), and the like from occurring. As a result, residual stress remains in the produced dicing die bond film, and there is a problem that peeling of the pressure-sensitive adhesive layer and the adhesive layer occurs at the interface between them during the above-described transportation in a low temperature condition or after long-term storage. Further, there is also a problem that a film lifting phenomenon occurs in a cover film that is provided on the adhesive layer, for example, due to shrinking of the dicing die bond film. Further, there is also a problem that a portion of the adhesive layer transfers onto the cover film.

### SUMMARY OF THE INVENTION

An object of the present invention is to provide a film for a semiconductor device in which an adhesive film and a cover film are sequentially laminated on a dicing film and that is capable of preventing interface delamination between the films, a film lifting phenomenon, and transfer of the adhesive film onto the cover film even during transportation or after long-term storage in a low temperature condition, and to provide a semiconductor device that is obtained using the film for a semiconductor device.

The present inventors investigated a film for a semiconductor device and a semiconductor device obtained by using the same to solve the conventional problems. As a result, it was found that the object can be achieved by adopting the following configuration, and the present invention was completed.

That is, the film for a semiconductor device according to the present invention, which is intended to solve the problems, is a film in which an adhesive film and a cover film are sequentially laminated on a dicing film and is characterized in that a peel force F₁ between the adhesive film and the cover film in a T type peeling test under conditions of a temperature of 23±2° C. and a peeling speed of 300 mm/min is within a range of 0.025 to 0.075 N/100 mm, a peel force F₂ between the adhesive film and the dicing film is within a range of 0.08 to 10 N/100 mm, and F₁ and F₂ satisfy a relationship of F₁<F₂.

A film for a semiconductor device is manufactured while applying a tensile force to a dicing film, an adhesive film, and a cover film from the viewpoint of preventing sagging, displacement of winding, positional shift, voids (air bubbles), and the like from occurring. As a result, the film for a semiconductor device is manufactured in a state that tensile residual strain exists in any of the films that constitute the film. This tensile residual strain causes shrinking of each film when it is transported or stored for a long time in a frozen condition of −30 to −10° C. or a low temperature condition of −5 to 10° C., for example. Further, the degree of shrinking differs because physical properties of the films differ. For example, the dicing film has the largest degree of shrinking among the films, and the cover film has the smallest degree of shrinking. As a result, interface delamination between the dicing film and the adhesive film is generated, and the film lifting phenomenon of the cover film is brought about.

A configuration that satisfies the relationship of F₁<F₂ is adopted in the present invention under the condition that the peel force F₁ between the adhesive film and the cover film is within a range of 0.025 to 0.075 N/100 mm and the peel force F₂ between the adhesive film and the dicing film is within a range of 0.08 to 10 N/100 mm. As described above, shrinking of the dicing film is the largest among the films. Therefore, by making the peel force F₂ between the adhesive film and the dicing film larger than the peel force F₁ between the adhesive film and the cover film, shrinking of the dicing film having the largest shrinking rate is suppressed and the interface delamination between the dicing film and the adhesive film and the film lifting phenomenon of the cover film are prevented. Further, part or the entirety of the adhesive film can be prevented from being transferred onto the cover film.

In the above-described configuration, the tensile residual strain may exist in at least any of the dicing film, the adhesive film, and the cover film. The “tensile residual strain” means that strain remains when a tensile force is applied onto the dicing film, the adhesive film, or the cover film in the longitudinal direction (that is, the MD (machine direction) of the film) or the width direction (that is, the TD (transverse direction) that is perpendicular to the longitudinal direction).

In the above-described configuration, the glass transition temperature of an adhesive composition in the adhesive film is preferably within a range of −20 to 50° C. By making the glass transition temperature of the adhesive composition −20° C. or more, the tackiness of the adhesive film at the B-stage is kept from becoming large, and good handling properties can be maintained. Further, a phenomenon that apart of the dicing film melts and the pressure-sensitive adhesive attaches to the semiconductor chips can be prevented. As a result, a good pickup property of the semiconductor chips can be maintained. On the other hand, by making the glass transition temperature 50° C. or less, a decrease in the fluidity of the adhesive film can be prevented. Further, good tackiness to the semiconductor wafer can be maintained. In the case where the adhesive film is of a thermosetting type, the glass transition temperature of the adhesive composition refers to a temperature before thermosetting.

In the above-described configuration, the adhesive film is preferably of a thermosetting type, and the tensile modulus at 23° C. before thermosetting is preferably within a range of 50 to 2000 MPa. By making the tensile storage modulus 50 MPa or more, a phenomenon that a part of the pressure-sensitive adhesive layer melts and the pressure-sensitive adhesive attaches to the semiconductor chips can be prevented. On the other hand, by making the tensile storage modulus 2000 MPa or less, good tackiness to the semiconductor wafer and the substrate can also be maintained.

In the above-described configuration, the dicing film has an ultraviolet curing-type pressure-sensitive adhesive layer laminated on the base material, and the tensile modulus at 23° C. of the pressure-sensitive adhesive layer after ultraviolet curing is preferably within a range of 1 to 170 MPa. By making the tensile modulus of the dicing film 1 MPa or more, a good pickup property can be maintained. On the other hand, by making the tensile modulus 170 MPa or less, the generation of chip fly during dicing can be prevented.

The semiconductor device according to the present invention is manufactured using the film for a semiconductor device described above.

With the film for a semiconductor device according to the present invention, the interface delamination between the films and the film lifting phenomenon that are caused by the tensile residual strain and transfer of the adhesive film onto the cover film can be prevented even when it is transported or stored for a long time in a frozen condition of −30 to −10° C. or a low temperature condition of −5 to 10° C. by making the peel force F₁ between the adhesive film and the cover film be within a range of 0.025 to 0.075 N/100 mm, making the peel force F₂ between the adhesive film and the dicing film be within a range of 0.08 to 10 N/100 mm, and satisfying the relationship of F₁<F₂. As a result, chip fly and chipping of semiconductor chips during dicing of the semiconductor wafer can be prevented by preventing the interface delamination between the dicing film and the adhesive film, for example. Further, voids (air bubbles) and wrinkles between the adhesive film and the semiconductor wafer can be prevented from occurring even when the semiconductor wafer is mounted on the adhesive film by preventing the film lifting phenomenon of the cover film. That is, the present invention can provide a film for a semiconductor device which can be used for manufacturing a semiconductor device with improved yield.

### BRIEF DESCRIPTION OF THE DRAWINGS

FIG. 1 is a sectional drawing showing an outline of a film for a semiconductor device according to one embodiment of the present invention; and

FIG. 2 is a schematic drawing to explain a process of manufacturing the film for a semiconductor device.

### DETAILED DESCRIPTION OF THE PREFERRED EMBODIMENTS

The film for a semiconductor device according to this embodiment is explained in the following.

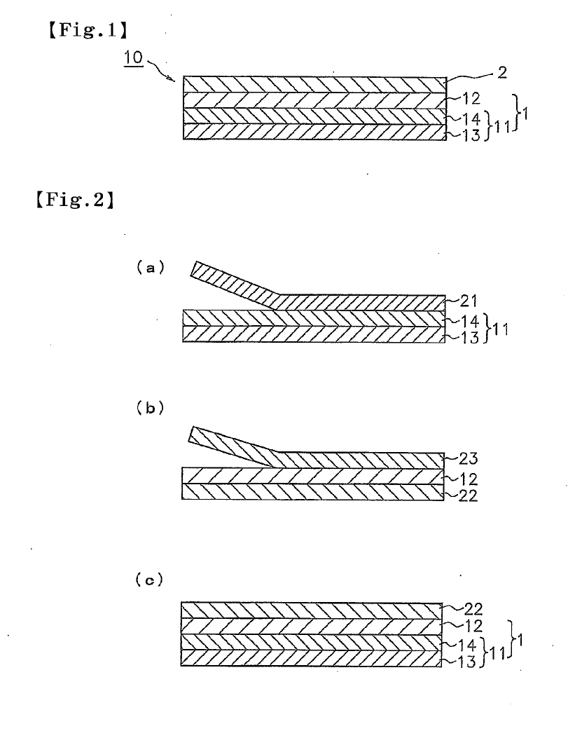

As shown in FIG. 1, a film for a semiconductor device 10 of this embodiment has a structure in which a cover film 2 is laminated on a dicing die bond film 1. The dicing die bond film 1 has a structure in which a die bond film 12 is laminated on a dicing film 11, and the dicing film 11 has a structure in which a pressure-sensitive adhesive layer 14 is laminated on a base material 13. The die bond film 12 corresponds to the adhesive film of the present invention.

The adhesive film of the present invention can be used as a die bond film or a film for a backside of a flip-chip semiconductor. The film for a backside of a flip-chip semiconductor is used for forming the backside of a semiconductor element (for example, a semiconductor chip) that is flip-chip-connected onto an adherend (for example, various types of substrates such as a lead frame and a circuit board).

The film for a semiconductor device of the present invention has a configuration in which the adhesive film and the cover film are sequentially laminated on the dicing film. An adhesive film with a dicing sheet has a structure in which the adhesive film is laminated on the dicing film. When the adhesive film is the die bond film, the adhesive film with a dicing sheet corresponds to the dicing die bond film.

The peel force F₁ between the die bond film 12 and the cover film 2 is smaller than the peel force F₂ between the die bond film 12 and the dicing film 11. The film for a semiconductor device 10 is manufactured by laminating the dicing film 11, the die bond film 12, and the cover film 2 while applying a tensile force to these films from the viewpoint of preventing the generation of sagging, displacement of winding, positional shift, voids (air bubbles), and the like in the manufacturing process. Therefore, tensile residual stress exists in each film. This tensile residual stress causes shrinking in the films when the films are transported or stored for a long time in a frozen condition of −30 to −10° C. or a low temperature condition of −5 to 10° C., for example. For example, the degree of shrinking is the largest in the dicing film and the degree of shrinking is the smallest in the cover film. In the film for a semiconductor device according to this embodiment, interface delamination between the films and the film lifting phenomenon of the cover film 2 that are caused by a difference in shrinking among the films can be prevented by making the relationship of the peel forces F₁ and F₂ be F₁<F₂. Further, part or the entirety of the die bond film 12 can be prevented from being transferred onto the cover film 2.

The peel force F₁ between the die bond film 12 and the cover film 2 is preferably within a range of 0.025 to 0.075 N/100 mm, more preferably within a range of 0.03 to 0.06 N/100 mm, and especially preferably within a range of 0.035 to 0.05 N/100 mm. When the peel force F₁ is less than 0.025 N/100 mm, each of the die bond film 12 and the cover film 2 shrinks at a different shrinking rate, and accordingly, there is a case where the film lifting phenomenon of the cover film 2 occurs when the film is transported or stored for a long time in a frozen condition of −30 to −10° C. or a low temperature condition of −5 to 10° C., for example. Further, there is a case where wrinkles, displacement of winding, and mixing of foreign objects are generated during the conveyance of the film for a semiconductor device 10, and the like. Further, there is a case where voids (air bubbles) are generated between the die bond film 12 and the semiconductor wafer during mounting of the semiconductor wafer. On the other hand, when the peel force F₁ is larger than 0.075 N/100 mm, adhesion of the die bond film 12 with the cover film 2 is too strong, and there is a case where the adhesive (the detail is described later) that constitutes the die bond film 12 transfers onto part or the entire surface during peeling or shrinking of the cover film 2. The value of the peel force F₁ means the peel force between the die bond film 12 before thermosetting and the cover film 2 in the case where the die bond film 12 is of a thermosetting type.

The peel force F₂ between the die bond film 12 and the dicing film 11 is preferably within a range of 0.08 to 10 N/100 mm, more preferably within a range of 0.1 to 6 N/100 mm, and especially preferably within a range of 0.15 to 0.4 N/100 mm. When the peel force F₂ is less than 0.08 N/100 mm, each of the dicing film 11 and the die bond film 12 shrinks at a different shrinking rate, and accordingly, there is a case where interface delamination between the dicing film 11 and the die bond film 12 occurs when the films are transported or stored for a long time in a frozen condition of −30 to −10° C. or a low temperature condition of −5 to 10° C., for example. Further, there is a case where wrinkles, displacement of winding, mixing of foreign objects, and voids are generated during the conveyance of the film for a semiconductor device 10, and the like. Further, there is a case where chip fly and chipping are generated when the semiconductor wafer is diced. On the other hand, when the peel force F₂ is larger than 10 N/100 mm, peeling of the die bond film 12 from the pressure-sensitive adhesive layer 14 becomes difficult during pickup of the semiconductor chips, and there is a case where pickup failure of the semiconductor chip is brought about. Further, there is a case where the pressure-sensitive adhesive (the detail is described later) that constitutes the pressure-sensitive adhesive layer 14 attaches onto the semiconductor chips with an adhesive. The numerical range of the peel force F₂ encompasses a case where the pressure-sensitive adhesive layer in the dicing film 11 is of an ultraviolet curing-type and the film 11 is cured to a certain degree by irradiation with an ultraviolet in advance. The curing of the pressure-sensitive adhesive layer by irradiation with an ultraviolet may be before or after pasting to the die bond film 12.

The values of the peel forces F₁ and F₂ are values that were measured by a T type peeling test (JIS K6854-3) carried out under conditions of a temperature of 23±2° C., a peeling speed of 300 mm/min, and a distance between chucks of 100 mm. “Autograph AGS-H” (trade name) manufactured by Shimadzu Corporation was used as a tensile tester.

The base material 13 in the dicing film 11 serves as a strength base of not only the dicing film 11 but also the film for a semiconductor device 10. Examples thereof include polyolefin such as low-density polyethylene, straight chain polyethylene, intermediate-density polyethylene, high-density polyethylene, very low-density polyethylene, random copolymer polypropylene, block copolymer polypropylene, homopolypropylene, polybutene, and polymethylpentene; an ethylene-vinylacetate copolymer; an ionomer resin; an ethylene(meth)acrylic acid copolymer; an ethylene(meth)acrylic acid ester (random or alternating) copolymer; an ethylene-butene copolymer; an ethylene-hexene copolymer; polyurethane; polyester such as polyethyleneterephthalate and polyethylenenaphthalate; polycarbonate; polyetheretherketone; polyimide; polyetherimide; polyamide; whole aromatic polyamides; polyphenylsulfide; aramid (paper); glass; glass cloth; a fluorine resin; polyvinyl chloride; polyvinylidene chloride; a cellulose resin; a silicone resin; metal (foil); and paper. When the pressure-sensitive adhesive layer 14 is of an ultraviolet curing-type, a base material having ultraviolet transmissivity is preferable among base materials that are exemplified above as the base material 13.

Further, the material of the base material 13 includes a polymer such as a cross-linked body of the above resins. The above plastic film may be also used unstreched, or may be also used on which a monoaxial or a biaxial stretching treatment is performed depending on necessity. According to resin sheets in which heat shrinkable properties are given by the stretching treatment, etc., the adhesive area of the pressure-sensitive adhesive layer 14 and the die bond film 12 is reduced by thermally shrinking the base material 13 after dicing, and the recovery of the semiconductor chips (a semiconductor element) can be facilitated.

A known surface treatment such as a chemical or physical treatment such as a chromate treatment, ozone exposure, flame exposure, high voltage electric exposure, and an ionized ultraviolet treatment, and a coating treatment by an undercoating agent (for example, a tacky substance described later) can be performed on the surface of the base material 13 in order to improve adhesiveness, holding properties, etc. with the adjacent layer.

The same type or different type of base material can be appropriately selected and used as the base material 13, and a base material in which a plurality of types are blended can be used depending on necessity. Further, a vapor-deposited layer of a conductive substance composed of a metal, an alloy, an oxide thereof, etc. and having a thickness of about 30 to 500 angstrom can be provided on the base material 13 in order to give an antistatic function to the base material 13. The base material 13 may be a single layer or a multi layer of two or more types.

The thickness of the base material 13 is not especially limited, and can be appropriately decided. However, it is about 5 to 200 μm, for example. The thickness is not especially limited as long as it is a thickness with which the base material can withstand the tensile force by the die bond film 12 due to heat shrinking.

The pressure-sensitive adhesive that is used to form the pressure-sensitive adhesive layer 14 is not especially limited, and a general pressure-sensitive adhesive such as an acrylic pressure-sensitive adhesive or a rubber pressure-sensitive adhesive can be used. The pressure-sensitive adhesive is preferably an acrylic pressure-sensitive adhesive containing an acrylic polymer as a base polymer in view of clean washing of electronic components such as a semiconductor wafer and glass, which are easily damaged by contamination, with ultrapure water or an organic solvent such as alcohol.

Specific examples of the acryl polymers include an acryl polymer in which acrylate is used as a main monomer component. Examples of the acrylate include alkyl acrylate (for example, a straight chain or branched chain alkyl ester having 1 to 30 carbon atoms, and particularly 4 to 18 carbon atoms in the alkyl group such as methylester, ethylester, propylester, isopropylester, butylester, isobutylester, sec-butylester, t-butylester, pentylester, isopentylester, hexylester, heptylester, octylester, 2-ethylhexylester, isooctylester, nonylester, decylester, isodecylester, undecylester, dodecylester, tridecylester, tetradecylester, hexadecylester, octadecylester, and eicosylester) and cycloalkyl acrylate (for example, cyclopentylester, cyclohexylester, etc.). These monomers may be used alone or two or more types may be used in combination. All of the words including “(meth)” in connection with the present invention have an equivalent meaning.

The acrylic polymer may optionally contain a unit corresponding to a different monomer component copolymerizable with the above-mentioned alkyl ester of (meth)acrylic acid or cycloalkyl ester thereof in order to improve the cohesive force, heat resistance or some other property of the polymer. Examples of such a monomer component include carboxyl-containing monomers such as acrylic acid, methacrylic acid, carboxyethyl(meth)acrylate, carboxypentyl(meth)acrylate, itaconic acid, maleic acid, fumaric acid, and crotonic acid; acid anhydride monomers such as maleic anhydride, and itaconic anhydride; hydroxyl-containing monomers such as 2-hydroxyethyl(meth)acrylate, 2-hydroxypropyl(meth)acrylate, 4-hydroxybutyl(meth)acrylate, 6-hydroxyhexyl(meth)acrylate, 8-hydroxyoctyl(meth)acrylate, 10-hydroxydecyl(meth)acrylate, 12-hydroxylauryl(meth)acrylate, and (4-hydroxylmethylcyclohexyl)methyl(meth)acrylate; sulfonic acid group containing monomers such as styrenesulfonic acid, allylsulfonic acid, 2-(meth)acrylamide-2-methylpropanesulfonic acid, (meth)acrylamidepropanesulfonic acid, sulfopropyl(meth)acrylate, and (meth)acryloyloxynaphthalenesulfonic acid; phosphoric acid group containing monomers such as 2-hydroxyethylacryloyl phosphate; acrylamide; and acrylonitrile. These copolymerizable monomer components may be used alone or in combination of two or more thereof. The amount of the copolymerizable monomer(s) to be used is preferably 40% or less by weight of all the monomer components.

For crosslinking, the acrylic polymer can also contain multifunctional monomers if necessary as the copolymerizable monomer component. Such multifunctional monomers include hexane diol di(meth)acrylate, (poly)ethylene glycol di(meth)acrylate, (poly)propylene glycol di(meth)acrylate, neopentyl glycol di(meth)acrylate, pentaerythritol di(meth)acrylate, trimethylol propane tri(meth)acrylate, pentaerythritol tri(meth)acrylate, dipentaerythritol hexa(meth)acrylate, epoxy(meth)acrylate, polyester(meth)acrylate, urethane(meth)acrylate etc. These multifunctional monomers can also be used as a mixture of one or more thereof. From the viewpoint of adhesiveness etc., the use amount of the multifunctional monomer is preferably 30 wt % or less based on the whole monomer components.

Preparation of the above acryl polymer can be performed by applying an appropriate manner such as a solution polymerization manner, an emulsion polymerization manner, a bulk polymerization manner, and a suspension polymerization manner to a mixture of one or two or more kinds of component monomers for example. Since the pressure-sensitive adhesive layer preferably has a composition in which the content of low molecular weight materials is suppressed from the viewpoint of prevention of wafer contamination, and since those in which an acryl polymer having a weight average molecular weight of 300000 or more, particularly 400000 to 30000000 is as a main component are preferable from such viewpoint, the pressure-sensitive adhesive can be made to be an appropriate cross-linking type with an internal cross-linking manner, an external cross-linking manner, etc.

To increase the number-average molecular weight of the base polymer such as acrylic polymer etc., an external crosslinking agent can be suitably adopted in the pressure-sensitive adhesive. The external crosslinking method is specifically a reaction method that involves adding and reacting a crosslinking agent such as a polyisocyanate compound, epoxy compound, aziridine compound, melamine crosslinking agent, urea resin, anhydrous compound, polyamine, carboxyl group-containing polymer. When the external crosslinking agent is used, the amount of the crosslinking agent to be used is determined suitably depending on balance with the base polymer to be crosslinked and applications thereof as the pressure-sensitive adhesive. Generally, the crosslinking agent is preferably incorporated in an amount of about 5 parts by weight or less based on 100 parts by weight of the base polymer. The lower limit of the crosslinking agent is preferably 0.1 parts by weight or more. The pressure-sensitive adhesive may be blended not only with the components described above but also with a wide variety of conventionally known additives such as a tackifier, and aging inhibitor, if necessary.

The pressure-sensitive adhesive layer 14 can be formed of an ultraviolet curing-type pressure-sensitive adhesive. The adhesive power of the ultraviolet curing-type pressure-sensitive adhesive can be decreased easily by increasing the degree of crosslinking by irradiation with an ultraviolet, and a difference in the adhesive power with other portions may be created by irradiating only the portion that corresponds to the semiconductor wafer pasting portion of the pressure-sensitive adhesive layer 14 with an ultraviolet.

The tensile modulus of the dicing film 11 at 23° C. after curing the pressure-sensitive adhesive layer 14 with an ultraviolet is preferably within a range of 1 to 170 MPa, and more preferably within a range of 5 to 100 MPa. By making the tensile modulus 1 MPa or more, a good pickup property can be maintained. On the other hand, by making the tensile modulus 170 MPa or less, the generation of chip fly during dicing can be prevented. The irradiation with an ultraviolet is preferably performed at an ultraviolet accumulative amount of 30 to 1000 mJ/cm², for example. By making the ultraviolet accumulative amount 30 mJ/cm² or more, the pressure-sensitive adhesive layer 14 can be cured sufficiency, and excessive adhesion with the die bond film 12 can be prevented. As a result, a good pickup property can be exhibited during pickup of the semiconductor chips. Further, the pressure-sensitive adhesive of the pressure-sensitive adhesive layer 14 can be prevented from attaching to the die bond film 12 (so-called adhesive residue) after pickup. On the other hand, by making the ultraviolet accumulative amount 1000 mJ/cm² or less, an excessive decrease in the adhesive power of the pressure-sensitive adhesive layer 14 is prevented, and accordingly, falling out of the mounted semiconductor wafer due to peeling between the pressure-sensitive adhesive layer 14 and the die bond film 12 is prevented. Further, chip fly of the formed semiconductor chip can be prevented from occurring during dicing of the semiconductor wafer.

The value of the tensile modulus is obtained by the following measurement method. That is, a sample having a length of 10.0 mm, a width of 2 mm, and a cross-sectional area of 0.1 to 0.5 mm² is cut from the dicing film 11. A tensile test is performed on this sample in an MD direction at a measurement temperature of 23° C., a distance between chucks of 50 mm, and a tensile speed of 50 mm/min, and the changing amount (mm) due to stretching of the sample is measured. The value of the tensile modulus is obtained by drawing a tangent line at the initial rising part of the obtained S-S (Strain-Strength) curve and dividing the tensile strength where the tangent line corresponds to 100% elongation by the cross-sectional area of the dicing film 11.

The die bond film 12 may have a configuration that it is formed only on the semiconductor wafer pasting portion according to the shape of the semiconductor wafer in a planar view. In this case, the adhesive power of the portion corresponding to the semiconductor wafer pasting portion can be easily decreased by curing the ultraviolet curing-type pressure-sensitive adhesive layer 14 to match the shape of the die bond film 12. Because the die bond film 12 is pasted onto the portion where the adhesive power is decreased, the interface between the above-described portion of the pressure-sensitive adhesive layer 14 and the die bond film 12 has a characteristic of peeling easily during pickup. On the other hand, the portion that is not irradiated with an ultraviolet has a sufficient adhesive power.

As described above, the portion of the pressure-sensitive adhesive layer 14 that is formed of an uncured ultraviolet curing-type pressure-sensitive adhesive adheres to the die bond film 12, and the holding power can be secured during dicing. In such a way, the ultraviolet curing-type pressure-sensitive adhesive can support the die bond film 12 for fixing a chip-shaped semiconductor wafer such as a semiconductor chip onto an adherend such as a substrate with a good balance of adhesion and the peeling property. When the die bond film 12 is laminated only on the semiconductor wafer pasting portion, a wafer ring is fixed to the region on which the die bond film 12 is not laminated.

The ultraviolet curing-type pressure-sensitive adhesive has an ultraviolet curable functional group such as a carbon-carbon double bond, and one having adherability can be used without special limitation. An example of the ultraviolet curing-type pressure-sensitive adhesive is an adding-type ultraviolet curing-type pressure-sensitive adhesive in which an ultraviolet curable monomer component or oligomer component is added to a general pressure-sensitive adhesive such as an acrylic pressure-sensitive adhesive or a rubber pressure-sensitive adhesive.

Examples of the ultraviolet curable monomer component to be compounded include such as an urethane oligomer, urethane(meth)acrylate, trimethylolpropane tri(meth)acrylate, tetramethylolmethane tetra(meth)acrylate, pentaerythritol tri(meth)acrylate, pentaerythritol tetra(meth)acrylate, dipentaerythritol monohydroxypenta(meth)acrylate, dipentaerythritol hexa(meth)acrylate, and 1,4-butane dioldi(meth)acrylate. Further, the ultraviolet curable oligomer component includes various types of oligomers such as an urethane based, a polyether based, a polyester based, a polycarbonate based, and a polybutadiene based oligomer, and its molecular weight is appropriately in a range of about 100 to 30,000. The compounding amount of the ultraviolet ray curable monomer component and the oligomer component can be appropriately determined to an amount in which the adhesive strength of the pressure-sensitive adhesive layer can be decreased depending on the type of the pressure-sensitive adhesive layer. Generally, it is for example 5 to 500 parts by weight, and preferably about 40 to 150 parts by weight based on 100 parts by weight of the base polymer such as an acryl polymer constituting the pressure sensitive adhesive.

Further, besides the added type ultraviolet curable pressure sensitive adhesive described above, the ultraviolet curable pressure sensitive adhesive includes an internal ultraviolet curable pressure sensitive adhesive using an acryl polymer having a radical reactive carbon-carbon double bond in the polymer side chain, in the main chain, or at the end of the main chain as the base polymer. The internal ultraviolet curable pressure sensitive adhesives of an internally provided type are preferable because they do not have to contain the oligomer component, etc. that is a low molecular weight component, or most of them do not contain, they can form a pressure-sensitive adhesive layer having a stable layer structure without migrating the oligomer component, etc. in the pressure sensitive adhesive over time.

The above-mentioned base polymer, which has a carbon-carbon double bond, may be any polymer that has a carbon-carbon double bond and further has viscosity. As such a base polymer, a polymer having an acrylic polymer as a basic skeleton is preferable. Examples of the basic skeleton of the acrylic polymer include the acrylic polymers exemplified above.

The method for introducing a carbon-carbon double bond into any one of the above-mentioned acrylic polymers is not particularly limited, and may be selected from various methods. The introduction of the carbon-carbon double bond into a side chain of the polymer is easier in molecule design. The method is, for example, a method of copolymerizing a monomer having a functional group with an acrylic polymer, and then causing the resultant to condensation-react or addition-react with a compound having a functional group reactive with the above-mentioned functional group and a carbon-carbon double bond while keeping the radial ray curability of the carbon-carbon double bond.

Examples of the combination of these functional groups include a carboxylic acid group and an epoxy group; a carboxylic acid group and an aziridine group; and a hydroxyl group and an isocyanate group. Of these combinations, the combination of a hydroxyl group and an isocyanate group is preferable from the viewpoint of the easiness of reaction tracing. If the above-mentioned acrylic polymer, which has a carbon-carbon double bond, can be produced by the combination of these functional groups, each of the functional groups may be present on any one of the acrylic polymer and the above-mentioned compound. It is preferable for the above-mentioned preferable combination that the acrylic polymer has the hydroxyl group and the above-mentioned compound has the isocyanate group. Examples of the isocyanate compound in this case, which has a carbon-carbon double bond, include methacryloyl isocyanate, 2-methacryloyloxyethyl isocyanate, and m-isopropenyl-α,α-dimethylbenzyl isocyanate. The used acrylic polymer may be an acrylic polymer copolymerized with any one of the hydroxyl-containing monomers exemplified above, or an ether compound such as 2-hydroxyethyl vinyl ether, 4-hydroxybutyl vinyl ether or diethylene glycol monovinyl ether.

The intrinsic type radial ray curable adhesive may be made only of the above-mentioned base polymer (in particular, the acrylic polymer), which has a carbon-carbon double bond. However, the above-mentioned radial ray curable monomer component or oligomer component may be incorporated into the base polymer to such an extent that properties of the adhesive are not deteriorated. The amount of the radial ray curable oligomer component or the like is usually 30 parts or less by weight, preferably from 0 to 10 parts by weight for 100 parts by weight of the base polymer.

In the case that the radial ray curable adhesive is cured with ultraviolet rays or the like, a photopolymerization initiator is incorporated into the adhesive. Examples of the photopolymerization initiator include α-ketol compounds such as 4-(2-hydroxyethoxy)phenyl(2-hydroxy-2-propyl)ketone, α-hydroxy-α,α′-dimethylacetophenone, 2-methyl-2-hydroxypropiophenone, and 1-hydroxycyclohexyl phenyl ketone; acetophenone compounds such as methoxyacetophenone, 2,2-dimethoxy-2-phenylacetophenone, 2,2-diethoxyacetophenone, and 2-methyl-1-[4-(methylthio)-phenyl]-2-morpholinopropane-1; benzoin ether compounds such as benzoin ethyl ether, benzoin isopropyl ether, and anisoin methyl ether; ketal compounds such as benzyl dimethyl ketal; aromatic sulfonyl chloride compounds such as 2-naphthalenesulfonyl chloride; optically active oxime compounds such as 1-phenone-1,1-propanedione-2-(o-ethoxycarbonyl)oxime; benzophenone compounds such as benzophenone, benzoylbenzoic acid, and 3,3′-dimethyl-4-methoxybenzophenone; thioxanthone compound such as thioxanthone, 2-chlorothioxanthone, 2-methylthioxanthone, 2,4-dimethylthioxanthone, isopropylthioxanthone, 2,4-dichlorothioxanthone, 2,4-diethylthioxanthone, and 2,4-diisopropylthioxanthone; camphorquinone; halogenated ketones; acylphosphonoxides; and acylphosphonates. The amount of the photopolymerization initiator to be blended is, for example, from about 0.05 to 20 parts by weight for 100 parts by weight of the acrylic polymer or the like which constitutes the adhesive as a base polymer.

The ultraviolet curing-type pressure-sensitive adhesive layer 14 can contain a compound that colors by irradiation with an ultraviolet as necessary. By containing the compound that colors by irradiation with an ultraviolet in the pressure-sensitive adhesive layer 14, only the portion irradiated with an ultraviolet can be colored. Accordingly, whether the pressure-sensitive adhesive layer 14 is irradiated with an ultraviolet or not can be visually determined immediately, and the semiconductor wafer pasting portion can be recognized easily, and the pasting of the semiconductor wafer is easy. Further, when detecting a semiconductor chip with a photosensor or the like, the detection accuracy improves, and no incorrect operation occurs during pickup of the semiconductor chip.

The compound that colors by irradiation with an ultraviolet is colorless or has a pale color before the irradiation with an ultraviolet. However, it is colored by irradiation with an ultraviolet. A preferred specific example of the compound is a leuco dye. Common leuco dyes such as triphenylmethane, fluoran, phenothiazine, auramine, and spiropyran can be preferably used. Specific examples thereof include 3-[N-(p-tolylamino)]-7-anilinofluoran, 3-[N-(p-tolyl)-N-methylamino]-7-anilinofluoran, 3-[N-(p-tolyl)-N-ethylamino]-7-anilinofluoran, 3-diethylamino-6-methyl-7-anilinofluoran, crystal violet lactone, 4,4′,4″-trisdimethylaminotriphenylmethanol, and 4,4′,4″-trisdimethylaminotriphenylmethane.

Examples of a developer that is preferably used with these leuco dyes include a prepolymer of a conventionally known phenolformalin resin, an aromatic carboxylic acid derivative, and an electron acceptor such as activated white earth, and various publicly known color developers can be used in combination for changing the color tone.

The compound that colors by irradiation with an ultraviolet may be included in the ultraviolet curing-type pressure-sensitive adhesive after it is dissolved in an organic solvent or the like, or may be included in the pressure-sensitive adhesive in the form of a fine powder. The ratio of use of this compound is 10% by weight or less, preferably 0.01 to 10% by weight, and more preferably 0.5 to 5% by weight in the pressure-sensitive adhesive layer 14. When the ratio of the compound exceeds 10% by weight, the curing of the portion of the pressure-sensitive adhesive layer 14 that corresponds to the semiconductor wafer pasting portion becomes insufficient because the ultraviolet that is radiated onto the pressure-sensitive adhesive layer 14 is absorbed too much by this compound, and the adhesive power may not decrease sufficiently. On the other hand, the ratio of the compound is preferably 0.01% by weight or more to color the compound sufficiently.

Further, when forming the pressure-sensitive adhesive layer 14 with the ultraviolet curing-type pressure-sensitive adhesive, the portion having a reduced adhesive power can be formed by using the base material 13 in which the entirety or part of the portion other than the portion corresponding to the semiconductor wafer pasting portion is protected from light, forming the ultraviolet curing-type pressure-sensitive adhesive layer 14 on this surface, and curing the portion corresponding to the semiconductor wafer pasting portion by irradiation with an ultraviolet. As a light-shielding material, a material that is capable of serving as a photo mask on a supporting film can be produced by printing, vapor deposition, or the like. According to such a manufacturing method, the film for a semiconductor device 10 of the present invention can be efficiently manufactured.

Moreover, when curing inhibition due to oxygen occurs during irradiation with an ultraviolet, it is desirable to shield oxygen (air) from the surface of the ultraviolet curing-type pressure-sensitive adhesive layer 14 in some way. Examples of the method include a method of covering the surface of the pressure-sensitive adhesive layer 14 with a separator and a method of performing irradiation with an ultraviolet in a nitrogen gas atmosphere.

The thickness of the pressure-sensitive adhesive layer 14 is not especially limited. However, it is preferably about 1 to 50 μm from the viewpoint of satisfying both of prevention of cracking on the cut surface of the chip and maintenance of the fixing of the die bond film. It is more preferably 2 to 30 μm, and further preferably 5 to 25 μm.

The die bond film 12 is a layer having an adhesive function, and a thermoplastic resin and a thermosetting resin may be used together or a thermoplastic resin may be used alone as its constituent.

The glass transition temperature of the adhesive composition in the die bond film 12 is preferably within a range of −20 to 50° C., and more preferably within a range of −10 to 40° C. When the glass transition temperature is −20° C. or more, the tackiness of the die bond film 12 in a B-stage state becomes large, and the handling property can be prevented from deteriorating. Further, attachment of the adhesive, that is melted by heat due to friction with the dicing blade during dicing of the semiconductor wafer, to the semiconductor chip can be prevented from causing pickup failure. On the other hand, by making the glass transition temperature 50° C. or less, the fluidity and adhesion with the semiconductor wafer can be prevented from decreasing. The glass transition temperature is a temperature at which tan δ (G″ loss modulus)/G′ (storage modulus)) measured under conditions of a temperature range of 50 to 250° C., a frequency of 0.01 Hz, a strain of 0.025%, and a temperature rising speed of 10° C./min using a viscoelasticity measurement apparatus (model RSA-II manufactured by Rheometric Scientific, Inc.) shows a maximum value.

The tensile storage modulus of the die bond film 12 at 23° C. before curing is preferably within a range of 50 to 2000 MPa, and more preferably within a range of 60 to 1000 MPa. By making the tensile storage modulus 50 MPa or more, attachment of the adhesive, that is melted by heat due to friction with a dicing blade during dicing of the semiconductor wafer, to the semiconductor chip can be prevented from causing pickup failure. On the other hand, by making the tensile storage modulus 2000 MPa or less, good adhesion with the semiconductor wafer to be mounted and the substrate to be die-bonded can be achieved.

The tensile storage modulus can be obtained by the following measurement method. The die bond film 12 having a thickness of 100 μm is formed by applying an adhesive composition solution onto a peeling liner to which a releasing treatment is performed, and drying the solution. This die bond film 12 is left in an oven at 150° C. for 1 hour, and then the tensile storage modulus of the die bond film 12 at 200° C. after curing is measured using a viscoelasticity measurement apparatus (model RSA-II manufactured by Rheometric Scientific, Inc.). More specifically, a measurement sample having a size of 30.0 mm in length×5.0 mm in width×0.1 mm in thickness is set in a jig for film tensile measurement, and the measurement is performed under conditions of a temperature range of 50 to 250° C., a frequency of 0.01 Hz, a strain of 0.025%, and a temperature rising speed of 10° C./min.

Examples of the thermoplastic resin include natural rubber, butyl rubber, isoprene rubber, chloroprene rubber, ethylene/vinyl acetate copolymer, ethylene/acrylic acid copolymer, ethylene/acrylic ester copolymer, polybutadiene resin, polycarbonate resin, thermoplastic polyimide resin, polyamide resins such as 6-nylon and 6,6-nylon, phenoxy resin, acrylic resin, saturated polyester resins such as PET and PBT, polyamideimide resin, and fluorine-contained resin. These thermoplastic resins may be used alone or in combination of two or more thereof. Of these thermoplastic resins, acrylic resin is particularly preferable since the resin contains ionic impurities in only a small amount and has a high heat resistance so as to make it possible to ensure the reliability of the semiconductor element.

The acrylic resin is not limited to any especial kind, and may be, for example, a polymer comprising, as a component or components, one or more esters of acrylic acid or methacrylic acid having a linear or branched alkyl group having 30 or less carbon atoms, in particular, 4 to 18 carbon atoms. Examples of the alkyl group include methyl, ethyl, propyl, isopropyl, n-butyl, t-butyl, isobutyl, amyl, isoamyl, hexyl, heptyl, cyclohexyl, 2-ethylhexyl, octyl, isooctyl, nonyl, isononyl, decyl, isodecyl, undecyl, lauryl, tridecyl, tetradecyl, stearyl, octadecyl, and dodecyl groups.

A different monomer which constitutes the above-mentioned polymer is not limited to any especial kind, and examples thereof include carboxyl-containing monomers such as acrylic acid, methacrylic acid, carboxyethyl acrylate, carboxypentyl acrylate, itaconic acid, maleic acid, fumaric acid, and crotonic acid; acid anhydride monomers such as maleic anhydride and itaconic anhydride; hydroxyl-containing monomers such as 2-hydroxyethyl(meth)acrylate, 2-hydroxypropyl(meth)acrylate, 4-hydroxybutyl(meth)acrylate, 6-hydroxyhexyl(meth)acrylate, 8-hydroxyoctyl(meth)acrylate, 10-hydroxydecyl(meth)acrylate, 12-hydroxylauryl(meth)acrylate, and (4-hydroxymethylcyclohexyl)methylacrylate; monomers which contain a sulfonic acid group, such as styrenesulfonic acid, allylsulfonic acid, 2-(meth)acrylamide-2-methylpropanesulfonic acid, (meth)acrylamidepropane sulfonic acid, sulfopropyl (meth)acrylate, and (meth)acryloyloxynaphthalenesulfonic acid; and monomers which contain a phosphoric acid group, such as 2-hydroxyethylacryloyl phosphate.

Examples of the above-mentioned thermosetting resin include phenol resin, amino resin, unsaturated polyester resin, epoxy resin, polyurethane resin, silicone resin, and thermosetting polyimide resin. These resins may be used alone or in combination of two or more thereof. Particularly preferable is epoxy resin, which contains ionic impurities which corrode semiconductor elements in only a small amount. As the curing agent of the epoxy resin, phenol resin is preferable.

The epoxy resin may be any epoxy resin that is ordinarily used as an adhesive composition. Examples thereof include bifunctional or polyfunctional epoxy resins such as bisphenol A type, bisphenol F type, bisphenol S type, brominated bisphenol A type, hydrogenated bisphenol A type, bisphenol AF type, biphenyl type, naphthalene type, fluorene type, phenol Novolak type, orthocresol Novolak type, tris-hydroxyphenylmethane type, and tetraphenylolethane type epoxy resins; hydantoin type epoxy resins; tris-glycicylisocyanurate type epoxy resins; and glycidylamine type epoxy resins. These may be used alone or in combination of two or more thereof. Among these epoxy resins, particularly preferable are Novolak type epoxy resin, biphenyl type epoxy resin, tris-hydroxyphenylmethane type epoxy resin, and tetraphenylolethane type epoxy resin, since these epoxy resins are rich in reactivity with phenol resin as an agent for curing the epoxy resin and are superior in heat resistance and so on.

The phenol resin is a resin acting as a curing agent for the epoxy resin. Examples thereof include Novolak type phenol resins such as phenol Novolak resin, phenol aralkyl resin, cresol Novolak resin, tert-butylphenol Novolak resin and nonylphenol Novolak resin; resol type phenol resins; and polyoxystyrenes such as poly(p-oxystyrene). These may be used alone or in combination of two or more thereof. Among these phenol resins, phenol Novolak resin and phenol aralkyl resin are particularly preferable, since the connection reliability of the semiconductor device can be improved.

About the blend ratio between the epoxy resin and the phenol resin, for example, the phenol resin is blended with the epoxy resin in such a manner that the hydroxyl groups in the phenol resin is preferably from 0.5 to 2.0 equivalents, more preferably from 0.8 to 1.2 equivalents per equivalent of the epoxy groups in the epoxy resin component. If the blend ratio between the two is out of the range, curing reaction therebetween does not advance sufficiently so that properties of the cured epoxy resin easily deteriorate.

In this embodiment, the die bond film 12 containing an epoxy resin, a phenol resin, and an acrylic resin is especially preferable. Because these resins have few ionic impurities and high heat resistance, reliability of the semiconductor chip can be secured. As for the compounding ratio in this case, the mixed amount of the epoxy resin and the phenol resin is 10 to 200 parts by weight to 100 parts by weight of the acrylic resin component.

A multifunctional compound that reacts with a functional 2.5 group at the ends of a molecular chain of a polymer may be added as a crosslinking agent to the die bond film 12 according to this embodiment during manufacture to crosslink to some degree in advance. With this operation, the tackiness at high temperature is improved, and the heat resistance can be improved.

The crosslinking agent may be one known in the prior art. Particularly preferable are polyisocyanate compounds, such as tolylene diisocyanate, diphenylmethane diisocyanate, p-phenylene diisocyanate, 1,5-naphthalene diisocyanate, and adducts of polyhydric alcohol and diisocyanate. The amount of the crosslinking agent to be added is preferably set to 0.05 to 7 parts by weight for 100 parts by weight of the above-mentioned polymer. If the amount of the crosslinking agent to be added is more than 7 parts by weight, the adhesive force is unfavorably lowered. On the other hand, if the adding amount is less than 0.05 part by weight, the cohesive force is unfavorably insufficient. A different polyfunctional compound, such as an epoxy resin, together with the polyisocyanate compound may be incorporated if necessary.

An inorganic filler maybe appropriately incorporated into the die bond film 12 of the present invention in accordance with the use purpose thereof. The incorporation of the inorganic filler makes it possible to confer electric conductance to the sheet, improve the thermal conductivity thereof, and adjust the elasticity. Examples of the inorganic fillers include various inorganic powders made of the following: a ceramic such as silica, clay, plaster, calcium carbonate, barium sulfate, aluminum oxide, beryllium oxide, silicon carbide or silicon nitride; a metal such as aluminum, copper, silver, gold, nickel, chromium, lead, tin, zinc, palladium or solder, or an alloy thereof; and carbon. These may be used alone or in combination of two or more thereof. Among these, silica, in particular fused silica is preferably used. The average particle size of the inorganic filler is preferably from 0.1 to 80 μm.

The compounded amount of the inorganic filler is preferably set to 0 to 80 parts by weight, more preferably 0 to 70 parts by weight to 100 parts by weight of the organic component.

If necessary, other additives may be incorporated into the die bond film 3, 3′ of the present invention. Examples thereof include a flame retardant, a silane coupling agent, and an ion trapping agent. Examples of the flame retardant include antimony trioxide, antimony pentaoxide, and brominated epoxy resin. These may be used alone or in combination of two or more thereof. Examples of the silane coupling agent include β-(3,4-epoxycyclohexyl)ethyltrimethoxysilane, γ-glycidoxypropyltrimethoxysilane, and γ-glycidoxypropylmethyldiethoxysilane. These may be used alone or in combination of two or more thereof. Examples of the ion trapping agent include hydrotalcite andbismuth hydroxide. These may be used alone or in combination of two or more thereof.

The thickness of the die bond film 12 is not particularly limited, and is, for example, from about 5 to 100 μm, preferably from about 5 to 50 μm.

The film for a semiconductor device 10 can have an antistatic function. By having an antistatic function, generation of static electricity at the adhesion and peeling of the film is prevented, and the circuit is prevented from being destroyed due to charging of the semiconductor wafer, and the like. The antistatic function can be given by an appropriate method such as a method of adding an antistatic agent or a conductive substance to the base material 13, the pressure-sensitive adhesive layer 14, or the die bond film 12 or a method of providing a conductive layer made of a complex that transfers charge to the base material 13 or a metal film. Preferred is a method by which impurity ions that can deteriorate a semiconductor wafer are hardly generated. Examples of the conductive substance (conductive filler) that is compounded to give conductivity or to improve the heat conductivity include spherical, needle-shaped, and flake-shaped metal powders of silver, aluminum, gold, copper, nickel, conductive alloys, and the like, metal oxides of alumina and the like, amorphous carbon black, and graphite. However, the die bond film 12 is preferably non-conductive in respect that electrical leaks can be prevented.

The die bond film 12 is protected by the cover film 2. The cover film 2 has a function as a protective material to protect the die bond film 12 until it is used. The cover film 2 is peeled when the semiconductor wafer is pasted onto the die bond film 12 of the dicing die bond film. Examples of the cover film 2 that can be used include a polyethylene terephthalate (PET) film, a polyethylene film, a polypropylene film, a plastic film whose surface is coated with a peeling agent such as a fluorine peeling agent or a long chain alkylacrylate peeling agent, and paper.

The thickness of the cover film 2 is not especially limited. However, it is preferably within a range of 0.01 to 2 mm, and more preferably within a range of 0.01 to 1 mm.

Next, a method of manufacturing the film for a semiconductor device 10 according to this embodiment is explained.

A method of manufacturing the film for a semiconductor device 10 according to this embodiment includes a step of producing the dicing film 11 by forming the pressure-sensitive adhesive layer 14 on the base material 13, a step of forming the die bond film 12 on a base material separator 22, a step of laminating the dicing film 11 and the die bond film 12 while a tensile force is applied to at least one of the films with the pressure-sensitive adhesive layer 14 and the die bond film 12 being pasting surfaces, a step of producing the dicing die bond film 1 by peeling the base material separator 22 from the die bond film 12, and a step of pasting the dicing die bond film 1 and the cover film 2 while applying a tensile force to at least one of the films with the die bond film 12 being a pasting surface.

The step of producing the dicing film 11 is performed as follows, for example. First, the base material 13 can be formed by a conventionally known film-forming method. The film-forming method includes, for example, a calendar film-forming method, a casting method in an organic solvent, an inflation extrusion method in a closed system, a T-die extrusion method, a co-extrusion method, and a dry lamination method.

Next, a pressure-sensitive adhesive composition solution is applied on the base material 13 to form a coated film and the coated film is dried under predetermined conditions (optionally crosslinked with heating) to form the pressure-sensitive adhesive layer 14. Examples of the application method include, but are not limited to, roll coating, screen coating and gravure coating methods. The drying condition is appropriately set according to the thickness and the material of the coating film. The drying is performed at a drying temperature of 80 to 150° C. and a drying time of 0.5 to 5 minutes, for example. The pressure-sensitive adhesive layer 14 may be formed by applying a pressure-sensitive adhesive composition onto a first separator 21 to form a coating film and then drying the coating film under the above-described drying condition. After that, the pressure-sensitive adhesive layer 14 is pasted onto the base material 13 together with the first separator 21. With this operation, the dicing film 11 is produced in which the pressure-sensitive adhesive layer 14 is protected by the first separator 21 (refer to FIG. 2(a)). The produced dicing film 11 may have a long rolled shape in which the film is wound up. In this case, it is preferable to wind the film while applying a tensile force in the longitudinal direction or the width direction so that sagging, displacement of winding, and positional shift do not occur in the dicing film 11. However, the dicing film 11 is wound up in a rolled shape in a state that tensile residual strain is remained due to application of the tensile force. There is a case where the dicing film 11 is stretched due to application of the tensile force during winding of the dicing film 11. However, the winding is not intended for stretching.

When a layer made from an ultraviolet curing-type pressure-sensitive adhesive that is cured by an ultraviolet in advance is adopted as the pressure-sensitive adhesive layer 14, the layer is formed as follows. That is, the pressure-sensitive adhesive layer is formed by forming a coating film by applying an ultraviolet curing-type pressure-sensitive adhesive composition onto the base material 13 and then drying the coating film (crosslinking by heating as necessary) under a prescribed condition. The coating method, the coating condition, and the drying condition can be the same as above. Further, the pressure-sensitive adhesive layer may be formed by forming a coating film by applying the ultraviolet curing-type pressure-sensitive adhesive composition onto the first separator 21 and then drying the coating film under the above-described drying condition. After that, the pressure-sensitive adhesive layer is transferred onto the base material 13. Further, the pressure-sensitive adhesive layer is irradiated with an ultraviolet under a prescribed condition. The irradiation condition of the ultraviolet is not especially limited. However, the ultraviolet accumulative amount is normally preferably within a range of 50 to 800 mJ/cm², and more preferably within a range of 100 to 500 mJ/cm². By adjusting the ultraviolet accumulative amount to be in this range, the peel force F₂ between the die bond film 12 and the dicing film 11 can be controlled to be within a range of 0.08 to 10 N/100 mm. When the ultraviolet accumulative amount is less than 30 mJ/cm², the curing of the pressure-sensitive adhesive layer 14 becomes insufficient, and there is a case where the peel force from the die bond film 12 becomes too large. As a result, the adhesion with the die bond film increases and the pickup property deteriorates. Further, there is a case where adhesive residue is generated on the die bond film. On the other hand, when the ultraviolet accumulative amount exceeds 1000 mJ/cm², there is a case where the peel force from the die bond film 12 becomes too small. As a result, there is a case where the interface delamination occurs between the pressure-sensitive adhesive layer 14 and the die bond film 12. As a result, there is a case where chip fly occurs during dicing of the semiconductor wafer. Further, there is a case where the base material 13 is thermally damaged. Further, the curing of the pressure-sensitive adhesive layer 14 proceeds excessively and the tensile modulus becomes too large and as a result, the expanding property deteriorates. The irradiation with an ultraviolet may be performed after the pasting step with the die bond film that is described later. In this case, the irradiation with an ultraviolet is preferably performed from the side of the base material 13.

The step of producing the die bond film 12 is performed as follows. That is, a coating film is formed by applying the adhesive composition solution for forming the die bond film 12 onto the base material separator 22 so that a prescribed thickness can be achieved. After that, the die bond film 12 is formed by drying the coating film under a prescribed condition. The coating method is not especially limited, and examples thereof include roll coating, screen coating, and gravure coating. The drying condition is appropriately set according to the thickness, the material, and the like of the coating film. Specifically, the drying is performed at a drying temperature of 70 to 160° C. and a drying time of 1 to 5 minutes. Further, the die bond film 12 may be formed by forming a coating film by applying the pressure-sensitive adhesive composition onto a second separator 23 and then drying the coating film under the above-described drying condition. After that, the die bond film 12 is pasted onto the base material separator 22 together with the second separator 23. With this operation, a laminated film is produced in which the die bond film 12 and the second separator 23 are sequentially laminated on the base material separator 23 (refer to FIG. 2(b)). The produced die bond film 12 may have a long rolled shape in which the film is wound up. In this case, it is preferable to wind the film while applying a tensile force in the longitudinal direction or the width direction so that sagging, displacement of winding, and positional shift do not occur in the die bond film 12. However, the die bond film 12 is wound up in a rolled shape in a state that the tensile residual strain is remained due to application of the tensile force. There is a case where the die bond film 12 is stretched due to application of the tensile force during winding of the die bond film 12. However, the winding is not intended for stretching.

Next, the dicing die bond film 1 is produced by pasting the dicing film 11 and the die bond film 12 together. That is, the first separator 21 is peeled from the dicing film 11, the second separator 23 is peeled from the die bond film 12, and then both of the films are pasted together so that the die bond film 12 and the pressure-sensitive adhesive layer 14 serve as the pasting surfaces (refer to FIG. 2(c)). At this time, the pressure-bonding is performed on at least one of the dicing film 11 and the die bond film 12 while applying a tensile force to the peripheral part of the film. When each of the dicing film 11 and the die bond film 12 has a long rolled shape in which the film is wound up, it is preferable to transport the dicing film 11 and the die bond film 12 without applying a tensile force in the longitudinal direction as much as possible. This is to suppress the tensile residual strain of these films. However, the tensile force may be applied within a range of 10 to 25 N from the viewpoint of preventing sagging, displacement of winding, positional shift, voids (air bubbles), and the like from occurring in the dicing film 11 and the die bond film 12. When the tensile force is within this range, interface delamination between the dicing film 11 and the die bond film 12 can be prevented from occurring even when the tensile residual strain remains in the dicing film 11 and the die bond film 12.

The pasting of the dicing film 11 and the die bond film 12 can be performed by pressure-bonding, for example. At this time, the laminating temperature is not especially limited. However, it is normally preferably 30 to 80° C., more preferably 30 to 60° C., and especially preferably 30 to 50° C. The linear pressure is not especially limited. However, it is normally preferably 0.1 to 20 kgf/cm, and more preferably 1 to 10 kgf/cm. The peel force F₂ between the die bond film 12 and the dicing film 11 can be controlled within a range of 0.08 to 10 N/100 mm by pasting the dicing film 11 to the die bond film 12 in which the glass transition temperature of the adhesive composition is within a range of −20 to 50° C. by adjusting the laminating temperature and/or the linear pressure to be in the above-described range(s). The peel force F₂ between the dicing film 11 and the die bond film 12 can be made large by making the laminating temperature high within the above-described range, for example. The peel force F₂ can also be made large by making the linear pressure large within the above-described range.

Next, the dicing die bond film 1 in which the pressure-sensitive adhesive layer 14 and the die bond film 12 are sequentially laminated on the base material 13 can be obtained by peeling the base material separator 22 from the die bond film 12. Then, the cover film 2 is pasted onto the die bond film 12 of the dicing die bond film 1. It is preferable to transport the dicing die bond film without applying a tensile force in the longitudinal direction as much as possible. Because only the base material 13 has a film shape and the lamination structure of the dicing die bond film as a support, the film can be easily stretched and the tensile residual strain is suppressed. However, the tensile force may be applied within a range of 10 to 25 N from the viewpoint of preventing sagging, displacement of winding, positional shift, voids (air bubbles), and the like from occurring in the dicing die bond film 1. When the tensile force is within this range, interface delamination between the dicing film 11 and the die bond film 12 and lifting of the cover film 2 can be prevented from occurring even when tensile residual strain remains in the dicing die bond film 1.

The pasting of the cover film 2 to the die bond film 12 in the dicing die bond film 1 is performed preferably by pressure-bonding. With this operation, the film for a semiconductor device 10 according to this embodiment is produced. At this time, the laminating temperature is not especially limited. However, it is preferably 30 to 80° C., more preferably 30 to 60° C., and especially preferably 30 to 50° C. The linear pressure is not especially limited. However, it is normally preferably 0.1 to 20 kgf/cm, and more preferably 1 to 10 kgf/cm. The peel force F₁ between the die bond film 12 and the cover film 2 can be controlled within a range of 0.025 to 0.075 N/100 mm by pasting the cover film 2 to the die bond film 12 in which the glass transition temperature of the adhesive composition is within a range of −20 to 50° C. by adjusting the laminating temperature and/or the linear pressure to be in the above-described range(s). The peel force F₁ between the dicing die bond film 1 and the cover film 2 can be made large by making the laminating temperature large within the above-described range, for example. Further, the peel force F₁ can also be made large by making the linear pressure large within the above-described range. It is preferable to transport the cover film 2 without applying the tensile force in the longitudinal direction as much as possible. This is to suppress the tensile residual strain on the cover film 2. However, the tensile force may be applied within a range of 10 to 25 N from the viewpoint of preventing sagging, displacement of winding, positional shift, voids (air bubbles), and the like from occurring in the cover film 2. The lifting of the cover film 2 from the dicing die bond film 1 can be prevented from occurring even when the tensile residual strain remains in the cover film 2.

The first separator 21 that is pasted onto the pressure-sensitive adhesive layer 14 of the dicing film 11, the base material separator 22 of the die bond film 12, and the second separator 23 that is pasted onto the die bond film 12 are not especially limited, and conventionally known films to which a releasing treatment has been performed can be used. Each of the first separator 21 and the second separator 23 has a function as a protective material. Further, the base material separator 22 has a function as a base material when transferring the die bond film 12 onto the pressure-sensitive adhesive layer 14 of the dicing film 11. The material that constitutes each of these films is not especially limited, and conventionally known materials can be adopted. Specific examples thereof include a polyethylene terephthalate (PET) film, a polyethylene film, a polypropylene film, a plastic film whose surface is coated with a peeling agent such as a fluorine peeling agent or a long chain alkylacrylate peeling agent, and paper.

### EXAMPLES

Below, preferred examples of the present invention are explained in detail. However, materials, addition amounts, and the like described in these examples are not intended to limit the scope of the present invention, and are only examples for explanation as long as there is no description of limitation in particular. Further, “part” means “ parts by weight.”

### Example 1

### <Production of Dicing Film>

An acrylic polymer A having a weight average molecular weight of 850,000 was obtained by charging 88.8 parts of 2-ethylhexyl acrylate (referred to as “2EHA” in the following), 11.2 parts of 2-hydroxyethyl acrylate (referred to as “HEA” in the following), 0.2 parts of benzoyl peroxide, and 65 parts of toluene into a reaction vessel equipped with a cooling tube, a nitrogen introducing tube, a thermometer, and a stirrer, and polymerizing the contents at 61° C. for 6 hours in a nitrogen air flow. The molar ratio of 2EHA to HEA was 100 mol to 20 mol. The measurement of the weight average molecular weight was performed as follows.

An acrylic polymer A′ was obtained by adding 12 parts (80 mol % relative to HEA) of 2-methacryloyloxyethyl isocyanate (referred to as “MOI” in the following) into the acrylic polymer A and performing an addition reaction treatment at 50° C. for 48 hours in an air flow.

Next, a pressure-sensitive adhesive solution was produced by adding 8 parts of an isocyanate crosslinking agent (trade name “Colonate L” manufactured by Nippon Polyurethane Industry Co., Ltd.) and 5 parts of a photopolymerization initiator (trade name “Irgacure 651” manufactured by Ciba Specialty Chemicals) into 100 parts of the acrylic polymer A′.

A pressure-sensitive adhesive layer having a thickness of 10 μm was formed by applying the pressure-sensitive adhesive solution that was prepared as described above onto the surface of a PET releasing liner (a first separator) to which a silicone treatment was performed and heat-crosslinking the product at 120° C. for 2 minutes. Then, a polyolefin film having a thickness of 100 μm (a base material) was pasted onto the surface of the pressure-sensitive adhesive layer. After that, it was kept at 50° C. for 24 hours.

Next, the PET releasing liner was peeled, and only a portion (a circular shape of 200 mm in diameter) that corresponds to the semiconductor wafer pasting portion (a circular shape of 200 mm in diameter) of the pressure-sensitive adhesive layer was directly irradiated with an ultraviolet. With this operation, the dicing film according to this example was produced. The irradiation condition was as described below. The tensile modulus of the pressure-sensitive adhesive layer was measured by the method described later, and the tensile modulus was 20 MPa.

### <Irradiation Condition of Ultraviolet>

Ultraviolet (UV) irradiation apparatus: High pressure mercury lamp

Ultraviolet accumulative amount: 500 mJ/cm²

Output: 120 W

Irradiation intensity: 200 mW/cm²

### <Production of Die Bond Film>

2 parts of an isocyanate crosslinking agent (trade name “Colonate HX” manufactured by Nippon Polyurethane Industry Co., Ltd.), 50 parts of an epoxy resin (trade name “Epicoat 1004” manufactured by JER), 10 parts of a phenol resin (trade name “Milex XLC-3L manufactured by Mitsui Chemicals, Inc.), and 30 parts of spherical silica (trade name “SO-25R” manufactured by Admatechs Co., Ltd., average particle size 0.5 μm) as an inorganic filler to 100 parts of an acrylic ester polymer (trade name “Paracron W-197CM” manufactured by Negami Chemical Industries Co., Ltd., Tg: 18° C.) having ethyl acrylate-methyl methacrylate as a main component were dissolved in methylethylketone, and the concentration was adjusted to be 18.0% by weight.

A coating layer was formed by applying this adhesive composition solution onto a release treated film (base material separator) by a fountain coater, and the coating layer was dried by directly blowing the layer with hot air at 150° C. at 10 m/s for 2 minutes. With this operation, a die bond film having a thickness of 25 μm was produced on the release treated film. A polyethylene terephthalate film (thickness 50 μm) to which a silicone release treatment had been performed was used as the release treated film.

### <Production of Dicing Die Bond Film>

Next, the dicing film and the die bond film were pasted together so that the pressure-sensitive adhesive layer and the die bond film serve as the pasting surfaces. The pasting was performed using a nip roll, and the pasting condition was set so that a laminating temperature T₁ was 50° C. and a linear pressure was 3 kgf/cm. Further, a dicing die bond film was produced by peeling the base material separator on the die bond film. The obtained dicing die bond film was wound in a roll, and the winding tensile force at this time was set to a level as which the film did not stretch, specifically 13 N.

### <Production of Film for Semiconductor Device>

A cover film made of a polyethylene terephthalate film (thickness 38 μm) was pasted onto the die bond film of the dicing die bond film. At this time, the pasting was performed while applying a tensile force of 17 N to each of the dicing die bond film and the cover film in the MD direction using a dancer roll to prevent positional shift, voids (air bubbles), and the like from occurring. The pasting was performed at a laminating temperature T₂ of 50° C. and a linear pressure of 3 kgf/cm using a nip roll. With this operation, the film for a semiconductor device according to this example was produced.

### Example 2

### <Production of Dicing Film>

The same dicing film as in Example 1 was used as the dicing film according to this example.

### <Production of Die Bond Film>

4 parts of an isocyanate crosslinking agent (trade name “Colonate HX” manufactured by Nippon Polyurethane Industry Co., Ltd.), 30 parts of an epoxy resin (trade name “Epicoat 1004” manufactured by JER), 15 parts of a phenol resin (trade name “Milex XLC-3L manufactured by Mitsui Chemicals, Inc.), and 60 parts of spherical silica (trade name “SO-25R” manufactured by Admatechs Co., Ltd., average particle size 0.5 μm) as an inorganic filler to 100 parts of an acrylic ester polymer (trade name “Paracron W-197C” manufactured by Negami Chemical Industries Co., Ltd., Tg: 18° C.) having ethyl acrylate-methyl methacrylate as a main component were dissolved in methylethylketone, and the concentration was adjusted to be 18.0% by weight.

A coating layer was formed by applying this adhesive composition solution onto a release treated film (base material separator) by a fountain coater, and the coating later was dried by directly blowing the layer with hot air at 150° C. at 10 m/s for 2 minutes. With this operation, a die bond film having a thickness of 25 μm was produced on the release treated film. A polyethylene terephthalate film (thickness 50 μm) to which a silicone release treatment had been performed was used as the release treated film.

### <Production of Dicing Die Bond Film>

Next, the dicing film and the die bond film were pasted together so that the pressure-sensitive adhesive layer and the die bond film serve as the pasting surfaces. At this time, the pasting was performed while applying a tensile force of 17 N to each of the dicing film and the die bond film in the MD direction using a dancer roll to prevent positional shift, voids (air bubbles), and the like from occurring. The pasting was performed using a nip roll, and the pasting condition was set so that a laminating temperature T₁ was 50° C. and a linear pressure was 3 kgf/cm. Further, a dicing die bond film was produced by peeling the base material separator on the die bond film. The obtained dicing die bond film was wound in a roll, and the winding tensile force at this time was set to a level at which the film did not stretch, specifically 13 N.

### <Production of Film for Semiconductor Device>

A cover film made of a polyethylene terephthalate film (thickness 38 μm) was pasted onto the die bond film of the dicing die bond film. At this time, the pasting was performed while applying a tensile force of 17 N to each of the dicing die bond film and the cover film in the MD direction using a dancer roll to prevent positional shift, voids (air bubbles), and the like from occurring. The pasting was performed at a laminating temperature T₂ of 50° C. and a linear pressure of 3 kgf/cm using a nip roll. With this operation, the film for a semiconductor device according to this example was produced.

### Comparative Example 1

### <Production of Dicing Film>

The same dicing film as in Example 1 was used as the dicing film according to this comparative example.

### <Production of Die Bond Film>

The same die bond film as in Example 1 was used as the die bond film according to this comparative example.

### <Production of Dicing Die Bond Film>

The dicing die bond film according to this comparative example was produced in the same manner as in Example 1 except that the laminating temperatures T₁ and T₂ when pasting the dicing film and the die bond film together were changed to 25° C.

### <Production of Film for Semiconductor Device>

The film for a semiconductor device according to this comparative example was produced by pasting a cover film made of a polyethylene terephthalate film to the dicing die bond film in the same manner as in Example 1.

### Comparative Example 2

### <Production of Dicing Film>

The same dicing film as in Example 1 was used as the dicing film according to this comparative example.

### <Production of Die Bond Film>

The same die bond film as in Example 1 was used as the die bond film according to this comparative example.

### <Production of Dicing Die Bond Film>

The dicing die bond film according to this comparative example was produced in the same manner as in Example 1 except that the laminating temperatures T₁ and T₂ when pasting the dicing film and the die bond film together were changed to 35° C.

### <Production of Film for Semiconductor Device>

The film for a semiconductor device according to this comparative example was produced by pasting a cover film made of a polyethylene terephthalate film to the dicing die bond film in the same manner as in Example 1.

### Comparative Example 3

### <Production of Dicing Film>

The same dicing film as in Example 1 was used as the dicing film according to this comparative example.

### <Production of Die Bond Film>

2 parts of an isocyanate crosslinking agent (trade name “Colonate HX” manufactured by Nippon Polyurethane Industry Co., Ltd.), 60 parts of an epoxy resin (trade name “Epicoat 1004” manufactured by JER), 10 parts of a phenol resin (trade name “Milex XLC-3L manufactured by Mitsui Chemicals, Inc.), and 15 parts of spherical silica (trade name “SO-25R” manufactured by Admatechs Co., Ltd., average particle size 0.5 μm) as an inorganic filler to 100 parts of a polymer (trade name “Paracron AS-3000” manufactured by Negami Chemical Industries Co., Ltd., Tg: −36° C.) having butyl acrylate as a main component were dissolved in methylethylketone, and the concentration was adjusted to be 18.0% by weight.

A coating layer was formed by applying this adhesive composition solution onto a release treated film (base material separator) by a fountain coater, and the coating later was dried by directly blowing the layer with hot air at 150° C. at 10 m/s for 2 minutes. With this operation, a die bond film having a thickness of 25 μM was produced on the release treated film. A polyethylene terephthalate film (thickness of 50 μm) to which a silicone release treatment had been performed was used as the release treated film.

### <Production of Dicing Die Bond Film>

The dicing die bond film according to this comparative example was produced by pasting the dicing film and the die bond film together in the same manner as in Example 1.

### <Production of Film for Semiconductor Device>

The film for a semiconductor device according to this comparative example was produced by pasting a cover film made of a polyethylene terephthalate film to the dicing die bond film in the same manner as in Example 1.

### (Measurement of Peel Force)

The measurement of the peel force between the die bond film and the cover film and the peel force between the dicing film and the die bond film for each of the films for a semiconductor device obtained in the examples and comparative examples was performed under conditions of a temperature of 23±2° C., a relative humidity of 55±5% Rh, and a peeling speed of 300 mm/min using a T type peeling tester (JIS K6854-3). Autograph AGS-H manufactured by Shimadzu Corporation was used as a tensile tester.

### (Tensile Modulus of Pressure-Sensitive Adhesive Layer)

A sample having a length of 10.0 mm, a width of 2 mm, and a sectional area of 0.1 to 0.5 mm² was cut out from each of the dicing films of the examples and comparative examples. A tensile test was performed on the sample in the MD direction at a temperature of 23° C., a distance between chucks of 50 mm, and a tensile speed of 20 mm/min, and the amount of change (mm) due to the stretch of the sample was measured. The tensile modulus was obtained by drawing a tangent at the initial rising part in the S-S (Strain-Strength) curve that was obtained in the tensile test, and dividing the tensile strength at which the tangent corresponds to 100% elongation by the sectional area of each of the dicing films.

(Tensile Modulus of Die Bond Film before Thermosetting)

The tensile modulus at 23° C. of each of the die bond films of the examples and comparative examples was measured using a viscoelasticity measurement apparatus (model RAS-II manufactured by Rheometric Scientific FE, Ltd.). More specifically, a measurement sample having a size of 30 mm in length×5 mm in width×0.1 mm in thickness was set in a jig for a film tensile measurement, and measurement was performed under conditions of a temperature of −40 to 250° C., a frequency of 0.01 Hz, and a temperature rising speed 10° C./min.

### (Existence of Interface Delamination and Film Lifting)

Film lifting in each of the films for a semiconductor device obtained in the examples and comparative examples was confirmed as follows. That is, each of the films for a semiconductor device was placed in a freezer at a temperature of −30±2° C. for 120 hours. Then, the film was placed in an environment of a temperature of 23±2° C. and a relative humidity of 55±5% Rh for 24 hours. After that, the existence of interface delamination and film lifting between the films in the film for a semiconductor device was evaluated. For the evaluation criteria, the case where interface delamination and film lifting were not visually observed was marked good, and the case where they were observed was marked poor.

### (Presence or Absence of Voids)

The presence or absence of voids in the films for a semiconductor device obtained in the examples and comparative examples was confirmed as follows. That is, the cover film was peeled from each of the films for a semiconductor device, and the semiconductor wafer was mounted on the die bond film. A semiconductor wafer having a size of 8 inches and a thickness of 75 μm was used. The mounting condition of the semiconductor wafer was as follows.

### <Pasting Condition>

Pasting apparatus: RM-300 manufactured by ACC

Pasting speed: 50 mm/sec

Pasting pressure: 0.2 MPa

Pasting temperature: 50° C.

Next, the presence or absence of voids (air bubbles) in the pasting surface of the dicing die bond film and the semiconductor wafer was confirmed with a microscope. The result is shown in Table 1.

### (Evaluation of Dicing and Pickup)

The cover film was peeled from each of the films for a semiconductor device, and the semiconductor wafer was mounted on the die bond film. A semiconductor wafer having a size of 8 inches and a thickness of 75 μm was used. The mounting condition of the semiconductor wafer was same as above.

Next, 30 semiconductor chips were formed by dicing the semiconductor wafer according to the following conditions. The presence or absence of chipping and chip fly was counted at this time. The result is shown in Table 1. The semiconductor chip was picked up together with the die bond film. The pickup was performed on 30 semiconductor chips (5 mm long×5 mm wide), and the success rate was calculated by counting the semiconductor chips with which the pickup was successful without any damage. The result is shown in Table 1. The pickup condition is as follows.

### <Dicing Condition>

Dicing method: single cut

Dicing apparatus: DISCO DFD6361 manufactured by DISCO Corporation

Dicing speed: 50 mm/sec

Dicing blade: 2050-HECC

Dicing blade rotation speed: 45,000 rpm

Dicing tape cut depth: 20 μm

Wafer chip size: 5 mm×5 mm

### <Pickup Condition>

Pickup apparatus: CPS-100 manufactured by NES Machinery

Number of needles: 9 needles

Needle pushing amount: 300 μm

Needle pushing speed: 10 mm/sec

Drawing-down amount: 3 mm

### (Measurement of Glass Transition Temperature Tg of Die Bond Film)

The glass transition temperature (Tg) of the die bond films of Examples 1 and 2 and Comparative Example 3 was measured using a viscoelasticity measurement apparatus (model RSA-II manufactured by Rheometric Scientific, Inc.). The measurement was performed under conditions of a temperature range of 50 to 250° C., a frequency of 0.01 Hz, a strain of 0.025%, and a temperature rising speed of 10° C./min, and the temperature when tan δ (G″ (loss modulus)/G′ (storage modulus)) shows a maximum value was defined as the Tg. As a result, the Tg of the die bond film of Example 1 was 39° C., the Tg of the die bond film of Example 2 was 47° C., and the Tg of the die bond film of Comparative Example 3 was −23° C.

### (Result)

As is obvious from Table 1, there was no interface delamination between the dicing film and the die bond film for the films for a semiconductor wafer of Examples 1 and 2, and also no film lifting phenomenon of the cover film was confirmed in these films. When a semiconductor wafer was mounted on the die bond film, no voids and wrinkles were generated. Further, chip fly of the semiconductor chip was not generated when dicing the semiconductor wafer, and the pickup property was good. Contrary to this, interface delamination occurred between the dicing film and die bond film for the film for a semiconductor wafer of Comparative Example 1 even though the pickup success rate was 100%, and the film lifting phenomenon of the cover film was confirmed. Further, voids and wrinkles were generated when mounting the semiconductor wafer. Further, interface delamination between the dicing film and the die bond film and film lifting of the cover film occurred in the film for a semiconductor device of Comparative Example 2, and chip fly and chipping occurred when dicing the semiconductor wafer. Further, the pickup became difficult and cracking and chipping of the semiconductor chip were confirmed in the film for a semiconductor device of Comparative Example 3 because the adhesion between the dicing film and the die bond film was strong.

TABLE 1

| | | | Comparative | Comparative | Comparative |
|---|---|---|---|---|---|
| | Example 1 | Example 2 | Example 1 | Example 2 | Example 3 |
| PEEL FORCE F₁ | 0.072 | 0.068 | 0.023 | 0.074 | 0.069 |
| (N/100 mm) | | | | | |
| PEEL FORCE F₂ | 0.47 | 0.082 | 0.047 | 0.069 | 0.73 |
| (N/100 mm) | | | | | |
| LAMINATING | 50 | 50 | 25 | 35 | 50 |
| TEMPERATURE | | | | | |
| T₁ (° C.) | | | | | |
| LAMINATING | 50 | 50 | 25 | 35 | 50 |
| TEMPERATURE | | | | | |
| T₂ (° C.) | | | | | |
| PRESENCE OR | good | good | poor | poor | good |
| ABSENCE OF | | | | | |
| INTERFACE | | | | | |
| DELAMINATION | | | | | |
| AND FILM | | | | | |
| LIFTING | | | | | |
| PRESENCE OR | Absent | Absent | Present | Present | Absent |
| ABSENCE OF | | | | | |
| VOIDS | | | | | |
| PRESENCE OR | Absent | Absent | Present | Present | Absent |
| ABSENCE OF | | | | | |
| CHIP FLY | | | | | |
| PICKUP | 100 | 100 | 100 | 60 | 20 |
| SUCCESS RATE | | | | | |
| (%) | | | | | |

The peel force F₁ in Table 1 represents the peel force between the dicing die bond film and the cover film, and the peel force F₂ in Table 1 represents the peel force between the dicing film and the die bond film. The laminating temperature T₁ represents the temperature when the dicing film and the die bond film were pasted together, and the laminating temperature T₂ represents the temperature when the dicing die bond film and the cover film were pasted together.

1. A film for a semiconductor device in which an adhesive film and a cover film are sequentially laminated on a dicing film, wherein
a peel force F₁ between the adhesive film and the cover film in a T type peeling test under conditions of a temperature of 23±2° C. and a peeling speed of 300 mm/min is within a range of 0.025 to 0.075 N/100 mm, a peel force F₂ between the adhesive film and the dicing film is within a range of 0.08 to 10 N/100 mm, and F₁ and F₂ satisfy a relationship of F₁<F₂.

2. The film for a semiconductor device according to claim 1, wherein
a tensile residual strain exists in at least any of the dicing film, the adhesive film, and the cover film.

3. The film for a semiconductor device according to claim 1, wherein
the glass transition temperature of an adhesive composition in the adhesive film is within a range of −20 to 50° C.

4. The film for a semiconductor device according to claim 1, wherein
the adhesive film is of a thermosetting type, and the tensile modulus at 23° C. before thermosetting is within a range of 50 to 2000 MPa.

5. The film for a semiconductor device according to claim 1, wherein
the dicing film has an ultraviolet curing-type pressure-sensitive adhesive layer laminated on a base material, and the tensile modulus at 23° C. of the pressure-sensitive adhesive layer after ultraviolet curing is within a range of 1 to 170 MPa.

6. A semiconductor device manufactured using the film for a semiconductor device according to claim 1.

7. The film for a semiconductor device according to claim 2, wherein
the glass transition temperature of an adhesive composition in the adhesive film is within a range of −20 to 50° C.
